(19) United States
(12) Patent Application Publication
(10) Pub. No.: US 2025/0130272 A1
(43) Pub. Date: Apr. 24, 2025

(54) DETECTING DEBRIS IN PAYMENT CARD READERS

(71) Applicant: Wayne Fueling Systems LLC, Austin, TX (US)

(72) Inventors: Richard Chism, Austin, TX (US); Rick Ferreira, Austin, TX (US); Steve Calvert, Austin, TX (US)

(21) Appl. No.: 18/490,227

(22) Filed: Oct. 19, 2023

(51) Int. Cl. G01R 31/28

(52) U.S. Cl. CPC G01R 31/282

(57) ABSTRACT

Various exemplary devices, systems, and methods for detecting debris in payment card readers are provided. In general, a card reader configured to read a card for payment and/or other purpose(s) includes a slot configured to receive the card therein. In an exemplary embodiment, a tester is configured to be inserted into the card reader slot and identify whether debris is present in the slot that would prevent the card reader from properly reading data from a card inserted into the slot, e.g., from reading a chip of the card, etc. The tester is configured to be inserted into the card reader slot with the card reader on site at its installed location, e.g., as part of a fuel dispenser or other payment terminal.

### FIELD

The present disclosure relates generally to detecting debris in payment card readers.

### BACKGROUND

Fuel pumping using a fuel dispenser conventionally requires a user, such as a consumer or a site operator, to interact with a fuel dispenser. The fuel dispenser typically includes a display which can be associated with a keyboard and/or other input devices that allow a consumer to select a type of payment, select a fuel grade, and to initiate the fuel pumping. A typical way to pay for the fuel is for a user to swipe a payment card through a slot of a card reader of the fuel dispenser.

Although the card reader slot is intended to receive only payment cards, foreign matter can be introduced into the card reader slot and render the card reader slot unusable, such as by the foreign matter becoming stuck in the card reader slot so that payment cards cannot be used with the card reader until the foreign matter is removed and/or the foreign matter causing damage to the card reader slot and/or card reader itself that renders the card reader unusable until repaired by an authorized repair agent. For example, fuel dispensers are typically located in outdoor environments for safety and convenience. The card reader of a fuel dispenser is thus typically exposed to an outdoor environment where foreign matter in the outdoor environment, e.g., leaves, refuse, etc., can be accidentally introduced into the card reader slot, e.g., due to wind, etc. For another example, the card reader slot must be accessible to users. Matter not intended to be introduced into the card reader slot, e.g., non-payment cards, food, gum, paper, etc., can be accidentally or intentionally introduced into the card reader slot by the user.

Accordingly, there remains a need for improved payment card readers.

### SUMMARY

In general, devices, systems, and methods for detecting debris in payment card readers are provided.

In one aspect, a testing system is provided that in one embodiment includes a testing device having a first portion and a second portion. The first portion of the testing device includes an indicator configured to indicate a result of testing. The second portion of the testing device includes an electrical contact. The second portion of the testing device is configured to be inserted into a slot of a card reader configured to read a chip of a chip card. With the second portion of the testing device inserted as fully as possible into the slot, the indicator is configured to be activated if the electrical contact is operatively engaged with a chip reader of the card reader and to not be activated if the electrical contact is not operatively engaged with the chip reader of the card reader.

The testing system can include any number of variations. For example, the testing device can include an electrical path between the indicator and the electrical contact, in a default state the electrical path can be incomplete such that the indicator is not activated, and, with the second portion of the testing device inserted as fully as possible into the slot, the electrical path can be configured to be complete between the indicator and the electrical contact. Further, the indicator can include a light, the indicator being activated can include the light being illuminated, and the indicator not being activated can include the light not being illuminated.

For another example, with the second portion of the testing device inserted as fully as possible into the slot, the indicator not being activated can be indicative of foreign matter being present in the slot.

For yet another example, with the second portion of the testing device inserted as fully as possible into the slot, the first portion of the testing device can be located outside of the slot.

For another example, the testing system can also include the card reader including the chip reader. Further, the chip reader can include a chip pin configured to operatively engage the electrical contact, and/or a payment terminal can include the card reader. Further, the payment terminal can be a fuel dispenser, or the payment terminal can be one of an automatic teller machine, an electrical charging kiosk, an air machine, and a vending machine; and/or the testing device can include an electrical path between the indicator and the electrical contact, in a default state the electrical path can be incomplete such that the indicator is not activated, and, with the second portion of the testing device inserted as fully as possible into the slot, the chip pin can be configured to operatively engage the electrical contact so as to complete the electrical path between the indicator and the electrical contact.

In another embodiment, a testing system includes a testing device and a card reader. The testing device includes an indicator, an electrical contact, and an electrical path between the light and the electrical contact. The indicator is configured to indicate a result of testing. The card reader is of a payment terminal and includes a slot and a chip reader. In a default state, the electrical path is incomplete and the indicator is not activated. The testing device is configured to be partially inserted into the slot such that the electrical contact is operatively engaged with the chip reader. The electrical contact operatively engaging with the chip reader is configured to complete the electrical path and thereby cause the indicator to be activated.

The testing system can have any number of variations. For example, with the testing device inserted as fully as possible into the slot, the indicator not being activated can be indicative of foreign matter being present in the slot. Further, the indicator can include a light, the indicator being activated can include the light being illuminated, and the indicator not being activated can include the light not being illuminated.

For another example, the chip reader can include a chip pin configured to operatively engage the electrical contact.

For yet another example, the payment terminal can be a fuel dispenser.

For still another example, the payment terminal can be one of a fuel dispenser, an automatic teller machine, an electrical charging kiosk, an air machine, and a vending machine.

In another aspect, a testing method is provided that in one embodiment includes inserting a second portion of a testing device as fully as possible into a slot of a card reader such that an indicator of the testing device is either activated or not activated. The testing device has a first portion and a second portion. The first portion of the testing device includes the indicator. The second portion of the testing device includes an electrical contact. The second portion of the testing device is configured to be inserted into the slot of the card reader configured to read a chip of a chip card. With the second portion of the testing device inserted as fully as possible into the slot, the indicator is configured to be activated if the electrical contact is operatively engaged with a chip reader of the card reader and to not be activated if the electrical contact is not operatively engaged with the chip reader of the card reader.

The method can vary in any number of ways. For example, a payment terminal can include the card reader, and the payment terminal can be one of a fuel dispenser, an automatic teller machine, an electrical charging kiosk, an air machine, and a vending machine.

For another example, the indicator can include a light, the indicator being activated can include the light being illuminated, and the indicator not being activated can include the light not being illuminated.

In another embodiment, a testing method includes partially inserting a testing device into a slot of a card reader such that an indicator of the testing device is either activated or not activated. The testing device includes an electrical contact and an electrical path between the indicator and the electrical contact. The card reader is of a payment terminal and includes a chip reader. In a default state, the electrical path is incomplete and the indicator is not activated. The testing device is configured to be partially inserted into the slot such that the electrical contact is operatively engaged with the chip reader. The electrical contact operatively engaging with the chip reader is configured to complete the electrical path and thereby cause the indicator to be activated.

The testing method can have any number of variations. For example, the indicator not being activated can be indicative of foreign matter being present in the slot, and the indicator being activated can be indicative of foreign matter not being present in the slot.

For another example, the payment terminal can be one of a fuel dispenser, an automatic teller machine, an electrical charging kiosk, an air machine, and a vending machine.

For another example, the indicator can include a light, the indicator being activated can include the light being illuminated, and the indicator not being activated can include the light not being illuminated.

### BRIEF DESCRIPTION OF DRAWINGS

The embodiments described above will be more fully understood from the following detailed description taken in conjunction with the accompanying drawings. The drawings are not intended to be drawn to scale. For purposes of clarity, not every component may be labeled in every drawing. In the drawings:

FIG. 1 is a schematic view of one embodiment of a fuel dispenser including a card reader;

FIG. 2 is a perspective view of the fuel dispenser of FIG. 1;

FIG. 3 is a schematic view of one embodiment of a chip card;

FIG. 4 is a schematic view of one embodiment of a tester inserted into a slot of the card reader of FIG. 1; and

FIG. 5 is a schematic view of one embodiment of a computing system.

### DETAILED DESCRIPTION

Certain exemplary embodiments will now be described to provide an overall understanding of the principles of the structure, function, manufacture, and use of the devices, systems, and methods disclosed herein. One or more examples of these embodiments are illustrated in the accompanying drawings.

Further, in the present disclosure, like-named components of the embodiments generally have similar features, and thus within a particular embodiment each feature of each like-named component is not necessarily fully elaborated upon. Additionally, to the extent that linear or circular dimensions are used in the description of the disclosed systems, devices, and methods, such dimensions are not intended to limit the types of shapes that can be used in conjunction with such systems, devices, and methods. A person skilled in the art will recognize that an equivalent to such linear and circular dimensions can easily be determined for any geometric shape. Sizes and shapes of the systems and devices, and the components thereof, can depend at least on the dimensions of the subject in which the systems and devices will be used, the size and shape of components with which the systems and devices will be used, and the methods with which the systems and devices will be used.

Various exemplary devices, systems, and methods for detecting debris in payment card readers are provided. In general, a card reader configured to read a card for payment and/or other purpose(s) includes a slot configured to receive the card therein. Debris (e.g., foreign matter) can be introduced into the card reader slot, accidentally or intentionally, and render the card reader slot unusable, such as by the debris becoming stuck in the card reader slot so that payment cards cannot be used with the card reader until the debris is removed and/or the debris causing damage to the card reader slot and/or card reader itself that renders the card reader unusable until repaired by an authorized repair agent. In an exemplary embodiment, a tester is configured to be inserted into the card reader slot and identify whether debris is present in the slot that would prevent the card reader from properly reading data from a card inserted into the slot, e.g., from reading a chip of the card, etc. The tester is configured to be inserted into the card reader slot with the card reader on site at its installed location, e.g., as part of a fuel dispenser or other payment terminal. The tester may therefore allow the card reader to be tested on site without the merchant or other party providing the card reader to customers or other users having to return the card reader (alone or with its associated payment terminal) to a manufacturer or other authorized party for inspection, repair, or replacement. The merchant or other party will therefore not lose use of the card reader until the same card reader or a replacement card reader is received and installed.

A card reader can be under warranty and thus be subject to a warranty claim by the merchant or other party providing the card reader to customers or other users. The merchant or other party that returned the card reader to a manufacturer or other authorized party as part of the warranty claim thus loses use of the card reader until the same card reader or a replacement card reader is received and installed, and the manufacturer or other authorized party must spend time and money evaluating the warranty claim. In many circumstances the merchant or other party will not realize that the card reader is not defective, e.g., due to an electronic hardware and/or software malfunction, a missing part, etc., but has been rendered inoperable because of debris in the card reader's slot. Debris in the card reader's slot may not be a defect covered partially or fully under warranty, so time and money has been lost by both the merchant or other party who returned the card reader and the manufacturer or other authorized party that evaluated the warranty claim.

Whether or not debris in a card reader's slot is a defect covered partially or fully under warranty, repair or replacement of a card reader with debris in its slot can in many circumstances be performable on site. The tester may allow the presence of the debris to be detected on site and thus allow for the repair or replacement to occur on site, thereby allowing the card reader to be back in service faster than if the card reader was sent offsite for repair, replacement, and/or warranty evaluation.

In an exemplary embodiment, a payment terminal including a card reader is located outdoors and is configured to communicate with a point of sale (POS) that is located indoors. For example, the POS can be located inside of a store, and the payment terminal can be located outside of the store at the site of the store, e.g., in the store's parking lot, as a kiosk next to the store's front door, etc. POSs are typically located indoors for security reasons. Payment terminals may be located outdoors for any of a variety of reasons, such as because the good(s)/service(s) being paid for are dispensed outdoors by the payment terminal for safety, convenience, or other reasons, because it allows for good(s)/service(s) to be purchased from a merchant when the merchant's store in which the POS is located is closed, etc.

The payment terminal can have a variety of forms. In an exemplary embodiment, the payment terminal includes one of a fuel dispenser configured to accept payment for fuel to be dispensed via the fuel dispenser, and a terminal configured to accept payment for goods and services. Examples of goods and services include a parking space, a pharmacy item, groceries to be delivered, and the like. Examples of non-fuel dispenser payment terminals include automated teller machines (ATMs), electrical charging kiosks, vending machines, payment kiosks, and the like.

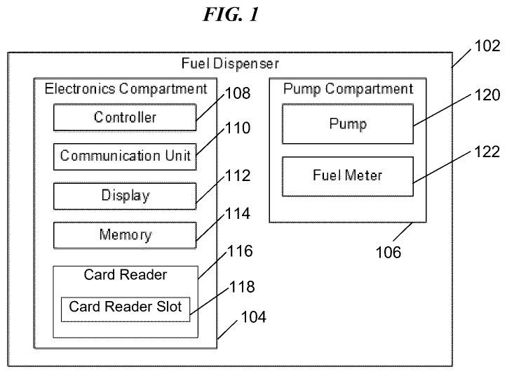

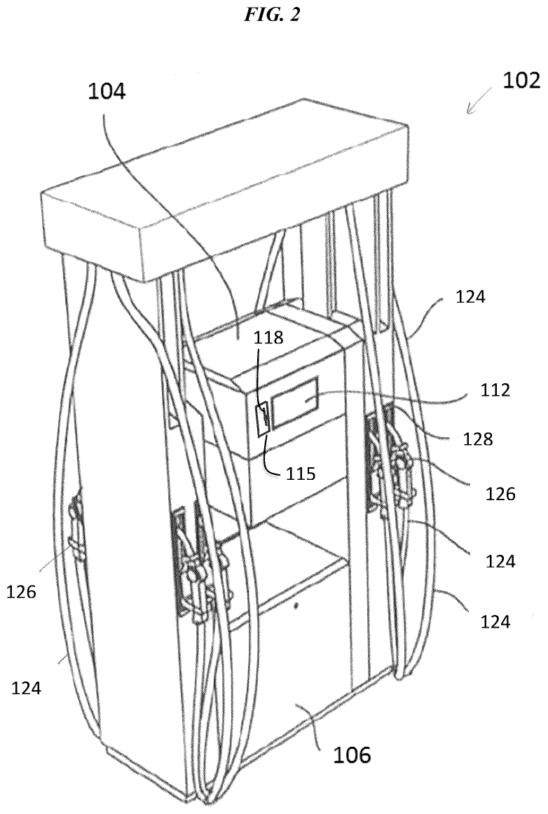

FIGS. 1 and 2 illustrate one embodiment of a payment terminal in the form of a fuel dispenser 102. As shown in FIGS. 1 and 2, the fuel dispenser 102 includes an electronics compartment 104 and a pump compartment 106. The electronics compartment 104 has therein electronics for facilitating payment for fuel (and/or other good and/or services) and for facilitating the dispensing of the fuel. The electronics include, for example, a controller (e.g., a processor or the like) 108 configured to control various electronic components of the fuel controller 102 and dispensing of the fuel from the pump compartment 106, a communication unit 110 configured to electronically communicate wired and/or wirelessly over a network, a display 112 configured to show information (e.g., media content, payment information, etc.) thereon, a memory 114 configured to store data therein that is readable by the controller 108, and a payment reader 115 including a card reader 116. Similar components can be located on the other side of the electronics compartment 104 that is obscured from view in FIG. 2. The payment reader can include one or more additional elements configured to receive input data from a user, e.g., a keypad, a mobile phone Bluetooth communication unit, etc. The fuel dispenser 102 can be configured for mobile payment in addition to payment through the payment terminal.

The card reader 116 includes a slot 118 configured to receive a card therein, such as a payment card (e.g., credit card, debit card, etc.), a customer loyalty card, etc. A card inserted into the slot 118 can be read by the card reader 116 in any of one or more various ways, as will be appreciated by a person skilled in the art. For example, the slot 118 can be configured to allow the card reader 116 to read a chip embedded in or otherwise included in the card inserted into the slot 118. For another example, the slot 118 can be configured to allow the card reader 116 to read a magnetic strip of the card inserted into the slot 118.

In some embodiments, the slot 118 includes a single slot. For example, a modern fuel dispenser may be configured to read chips of cards but not magnetic strips of cards so can include a single slot configured to allow the card reader 116 to read a card's chip. In other embodiments, the slot 118 includes a plurality of slots with each of the plurality of slots configured to allow the card reader 116 to read information differently, e.g., a first one of the slots configured to read a card's chip and a second one of the slots configured to read a card's magnetic strip, and/or to receive therein cards of different sizes.

The card reader 116 is configured to read a chip (e.g., a microchip) of a card inserted into the slot 118. Many card manufacturers have started to include a microchip and PIN (personal identification number) system into their cards. These types of cards are often referred to as “chip cards” or “EMV ICC cards,” and they can include a microchip on one end of the card that encodes payment data, as will be appreciated by a person skilled in the art. In use, the chip card is inserted into the slot 118, the card reader 116 reads data from the microchip, the controller 108 in operative communication with the card reader 116 prompts a user of the card to input a PIN (e.g., via a keypad or other input device of the fuel dispenser 102 or of a mobile phone or other external device in operative communication with the fuel dispenser 102), and the controller 108 (or external controller, such as at a remote third party payment system server, a cloud-based server, etc.) verifies whether the PIN is correct so as to allow user payment using the card.

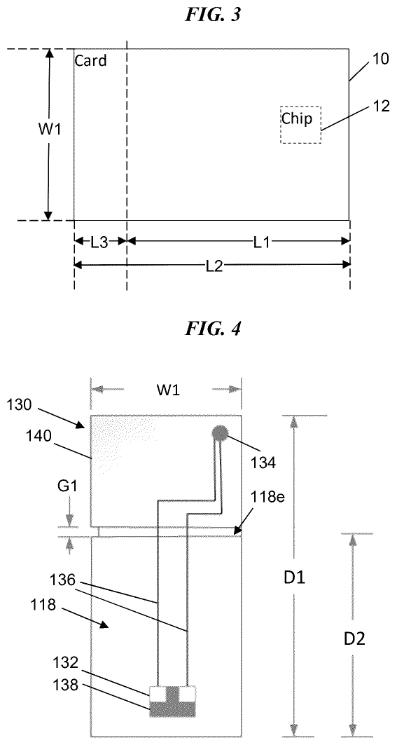

FIG. 3 illustrates one embodiment of a chip card 10 including a chip 12. The chip 12 is shown in phantom to indicate that the chip 12 is at least partially embedded in the card 10, e.g., for security and safety. A location of the chip 12 in/on the card 10 is a standard location used by card manufacturers so cards can be universally used throughout the world.

Using the card 10 of FIG. 3 by way of example, the slot 118 has a width that is greater than a width W1 of the card 10 so as to allow the card 10 to be inserted into the slot 118 without the card 10 being bent or warped. The card width W1 is a standard width used by card manufacturers so cards can be universally used throughout the world. In some embodiments, the slot 118 is configured to receive only a portion of the card 10 therein such that only a partial length L1 of the card 10 is received in the slot 118. The partial length L1 can vary in terms of its percentage of the card's total length L2, but the chip 12 is located along the partial length L1 so as to be receivable within the slot 118 for reading by the card reader 116. A length L3 of the card 10 not insertable into the card 10 is therefore available for the user to hold onto for safety and handling of the card 10. In other embodiments, the slot 118 is configured to receive an entirety of the card 10 therein such that the total length L2 of the card 10 is received in the slot 118. In such embodiments, as will be appreciated by a person skilled in the art, the card reader 116 includes a mechanism configured to eject the card 10 partially out of the slot 118 to allow the user to retrieve the card 10.

In some embodiments, the card reader 116 is configured to only read chip cards. In other embodiments, the card reader 116 is a multi-functional card reader configured to read chip cards and at least one other type of card, such as the card reader 116 also being configured to read a magnetic stripe of a card, as will be appreciated by a person skilled in the art.

A person skilled in the art will also appreciate that the card reader 116 can have various other configurations. Various exemplary embodiments of card readers are described further in, for example, U.S. Pat. No. 11,436,505 entitled “Anti-Skimming Card Reader” issued Sep. 6, 2022, which is hereby incorporated by reference in its entirety.

Referring again to FIGS. 1 and 2, the pump compartment 106 of the fuel dispenser 102 has therein a pump 120 configured to pump fuel from a fuel tank or other reservoir and has therein a fuel meter 122 configured to monitor fuel flow. The pump compartment 106 can include other elements to facilitate fuel dispensing, such as valves, a vapor recovery system, etc., as will be appreciated by a person skilled in the art. The pump compartment 106 is isolated from the electronics compartment 104 within the fuel dispenser 102 to facilitate safety, security, and/or maintenance, as will also be appreciated by a person skilled in the art. Fuel is thus not allowed to flow from the pump compartment 106 to the electronics compartment 104 and instead flows from the pump compartment 106 through hoses 124 to nozzles 126 for dispensing. When each hose 124 is not in use, the hose 124 hangs along the fuel dispenser 102, and its associated nozzle 126 is seated in a nozzle boot 128. As will be appreciated by a person skilled in the art, the nozzles 126 are each configured to dispense fuel from the fuel dispenser 102 as pumped therefrom by the pump 120. The illustrated fuel dispenser 102 includes four hoses 124 and four nozzles 126 on one side of the dispenser 102 and four hoses 124 and four nozzles 126 on the other side of the dispenser 102, but as will be appreciated by a person skilled in the art, the fuel dispenser 102 can include any number of hoses 124 and nozzles 126.

A person skilled in the art will also appreciate that the fuel dispenser 102 can have various other configurations. Various exemplary embodiments of fuel dispensers are described further in, for example, U.S. Pat. No. 10,214,411 entitled “Fuel Dispenser Communication” issued Feb. 26, 2019, U.S. Pat. No. 10,269,082 entitled “Intelligent Fuel Dispensers” issued Apr. 23, 2019, U.S. Pat. No. 10,577,237 entitled “Methods And Devices For Fuel Dispenser Electronic Communication” issued Mar. 3, 2020, U.S. Pat. No. 10,726,508 entitled “Intelligent Fuel Dispensers” issued Jul. 28, 2020, U.S. Pat. No. 11,276,051 entitled “Systems And Methods For Convenient And Secure Mobile Transactions” issued Mar. 15, 2022, U.S. Pat. No. 11,429,945 entitled “Outdoor Payment Terminals” issued Aug. 30, 2022, and U.S. Pat. App. Pub. No. 2023/0196360 entitled “Conducting Fuel Dispensing Transactions” published Jun. 22, 2023, which are hereby incorporated by reference in their entireties.

FIG. 4 illustrates one embodiment of a tester (also referred to herein as a “gauge” or a “testing device”) 130 configured to be inserted into the slot 118 of the card reader 116 and identify whether debris is present in the slot 118 that would prevent the card reader 116 from properly reading data from a card inserted into the slot 118, e.g., from reading a chip of the card such as the chip 12 of the card 10, etc. Although the tester 130 is described with respect to the card reader 116 of the fuel dispenser 102 of FIGS. 1 and 2 and the card 10 of FIG. 3, the tester 130 can be used similarly with other cards, other card readers, other fuel dispensers including a card reader with a slot, and other payment terminals including a card reader with a slot.

The tester 130 includes an electrical contact 132, an indicator 134, and an electrical path 136 (e.g., a conductive trace or other electrical path) electrically connecting the electrical contact 132 and the indicator 134.

A partial length D2 of the tester's total length D1 is configured to be inserted into the slot 118 (or other slot of a card reader, as discussed herein). The indicator 134 is located in a portion of the tester 130 that is not configured to be inserted into the slot 118. The indicator 134 is thus configured to be visible to a user of the tester 130 with the tester 130 inserted as completely as possible into the slot 118. The indicator 134 is a light in this illustrated embodiment but can be another type of indicator configured to indicate a result of testing to a user of the tester 130. The light can be a light emitting diode (LED) or other type of light and can include one or more individual lights. Other examples of the indicator 134 include mechanical indicators (e.g., a switch configured to move and emit an audible click or other sound, a movable cover configured to cover a symbol, a color, text, or other visual element and move in response to a testing result to show the underlying visual element, etc.) and electrical indicators (e.g., a visual display, an audible beep or other electronic sound, etc.).

The electrical contact 132 is located entirely along the partial length D2 of the tester 130 that is insertable into the slot 118. The electrical contact 132 is thus configured to be fully disposed in the slot 118. A location of the electrical contact 132 corresponds to the standard location of a chip of a chip card. A chip reader 138 of the card reader 116 is at a standard location to allow the card reader 116 to read a chip of a standard chip card inserted therein. The electrical contact 132 is therefore configured to operatively engage the chip reader 138 with the tester 130 inserted as fully as possible in the slot 118 because the electrical contact 132 is located similar to the card's chip 12. The chip reader 138 can have a variety of configuration, as will be appreciated by a person skilled in the art, and, as shown in FIG. 4, can include chip pins configured to operatively engage the electrical contacts 132 of the tester 130 with the tester 130 inserted into the slot 118 or, with the card 10 inserted into the slot 118, the chip 12 of the card 10.

The location of a chip reader may vary slightly between different card readers. Thus, in some embodiments, a gauge gap G1 may exist between a base portion 140 of the tester 130 and an open insertion end 118e of the slot 118. The base portion 140 is configured to be handheld by a user of the tester 130. The indicator 134 is located at the base portion 140.

The electrical contact 132 is configured to operatively engage the chip reader 138 of the card reader 116 that is configured to read data from the card's chip 12 (or other chip of a card, as discussed herein). The electrical path 136 is incomplete in a default state. With the electrical contact 132 operatively engaging the chip reader 138, voltage from the chip reader 138 is configured to complete the electrical path 136 between the electrical contact 132 and the indicator 134, thereby causing the indicator 134 to be activated, which in this illustrated embodiment is the light illuminating. The indicator 134 being activated (e.g., the light illuminating, a sound being audible, etc.) indicates to a user of the tester 130 that the slot 118 is not obstructed by debris that would prevent the card reader 116 (e.g., the chip reader 138) from reading data from the card's chip 12 (or other chip of a card, as discussed herein).

The indicator 134 not being activated when the tester 130 is inserted into the slot 118 indicates to the user of the tester 130 that the slot 118 is obstructed by debris that would prevent the card reader 116 (e.g., the chip reader 138) from reading data from the card's chip 12 (or other chip of a card, as discussed herein). The indicator not being activated prompts a user of the tester 130 to take at least one corrective action. One example of the corrective action is the user attempting to clear the slot 118 of debris so the card reader 116 can be used subsequently with a card without the card reader 116 and/or the fuel dispenser 102 having to be returned to a manufacturer or other authorized agent for repair or replacement. Another example of the corrective action is disabling the card reader 116 from accepting cards in the slot 118 until the slot 118 is cleared of debris. Yet another example of the corrective action is disabling the fuel dispenser 102 (or other payment terminal that includes the card reader being tested) until the slot 118 is cleared of debris. Still another example of the corrective action is to submit a work order to the manufacturer or other authorized agent for the card reader 116 to be repaired or replaced.

The tester 130 is configured to test the card reader slot 118 for debris without the card reader 116 having to be modified from its standard configuration since the tester 130 utilizes the card reader's existing chip reader 138. The card reader 116 therefore does not need any software updating or hardware modification, nor does the fuel dispenser 102, for the tester 130 to work properly with the card reader 116.

In some embodiments, the tester 130 also includes a magnetic stripe and a full chip interface with a port configured to provide additional information to an application so as to provide full port testing. In such embodiments, the tester 130 can be configured as a computing device. The application can be installed on the tester 130 or can be installed on a tablet, a mobile device, or other computing device configured to be in operative communication with the tester 130.

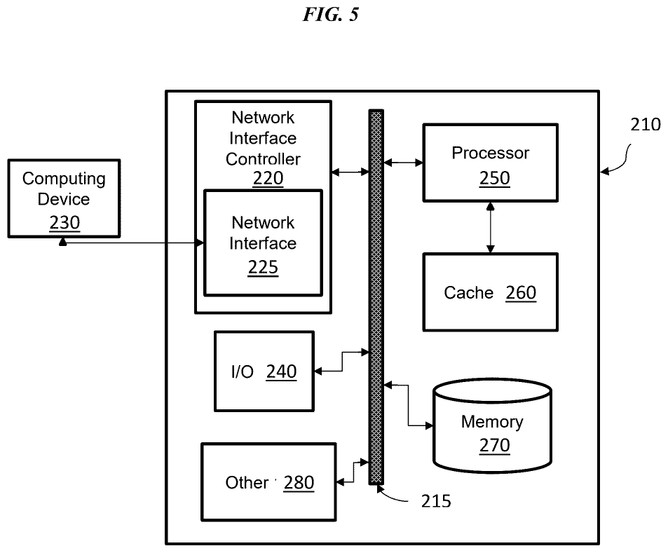

FIG. 5 illustrates one embodiment of a computing system 210 suitable for use in implementing computerized components described herein. In broad overview, the computing system 210 includes a processor 250 configured to perform actions in accordance with instructions, and memory devices 260 and/or 270 configured to store instructions and data. The illustrated example computing system 210 includes one or more processors 250 in communication, via a bus 215, with the memory 270 and with at least one network interface controller 220 with a network interface 225 for connecting to external devices 230, e.g., a computing device (such as a mobile phone, a tablet, a laptop, a server, etc.). The one or more processors 250 are also configured to be in communication, via the bus 215, with each other and with any I/O devices at an I/O interfaces 240, and any other devices 280. The processor 250 illustrated incorporates, or is directly connected to, the cache memory 260. Generally, a processor will execute instructions received from memory. In some embodiments, the computing system 210 can be configured within a cloud computing environment, a virtual or containerized computing environment, and/or a web-based microservices environment.

In more detail, the processor 250 can be any logic circuitry that processes instructions, e.g., instructions fetched from the memory 270 or cache 260. In many embodiments, the processor 250 is an embedded processor, a microprocessor unit or special purpose processor. The computing system 210 can be based on any processor, e.g., suitable digital signal processor (DSP), or set of processors, capable of operating as described herein. In some embodiments, the processor 250 can be a single core or multi-core processor. In some embodiments, the processor 250 can be composed of multiple processors.

The memory 270 can be any device suitable for storing computer readable data. The memory 270 can be a device with fixed storage or a device for reading removable storage media. Examples include all forms of non-volatile memory, media and memory devices, semiconductor memory devices (e.g., EPROM, EEPROM, SDRAM, flash memory devices, and all types of solid state memory), magnetic disks, and magneto optical disks. A computing device 210 can have any number of memory devices 270.

The cache memory 260 is generally a form of high-speed computer memory placed in close proximity to the processor 250 for fast read/write times. In some implementations, the cache memory 260 is part of, or on the same chip as, the processor 250.

The network interface controller 220 is configured to manage data exchanges via the network interface 225. The network interface controller 220 handles the physical, media access control, and data link layers of the Open Systems Interconnect (OSI) model for network communication. In some implementations, some of the network interface controller's tasks are handled by the processor 250. In some implementations, the network interface controller 220 is part of the processor 250. In some implementations, a computing device 210 has multiple network interface controllers 220. In some implementations, the network interface 225 is a connection point for a physical network link, e.g., an RJ 45 connector. In some implementations, the network interface controller 220 supports wireless network connections and an interface port 225 is a wireless Bluetooth transceiver. Generally, a computing device 210 can be configured to exchange data with other network devices 230, such as computing device 230, via physical or wireless links to a network interface 225. In some implementations, the network interface controller 220 implements a network protocol such as LTE, TCP/IP Ethernet, IEEE 802.11, IEEE 802.16, Bluetooth, or the like.

The other computing devices 230 are connected to the computing device 210 via a network interface port 225. The other computing device 230 can be a peer computing device, a network device, a server, or any other computing device with network functionality. For example, a computing device 230 can be a computing device associated with a user of the fuel dispenser 102 or the tester 130. In some embodiments, the computing device 230 can be a network device such as a hub, a bridge, a switch, or a router, connecting the computing device 210 to a data network such as the Internet.

In some uses, the I/O interface 240 supports an input device and/or an output device (not shown). In some uses, the input device and the output device are integrated into the same hardware, e.g., as in a touch screen. In some uses, such as in a server context, there is no I/O interface 240 or the I/O interface 240 is not used. In some uses, additional other components 280 are in communication with the computer system 210, e.g., external devices connected via a universal serial bus (USB).

The other devices 280 can include an I/O interface 240, external serial device ports, and any additional co-processors. For example, a computing system 210 can include an interface (e.g., a universal serial bus (USB) interface, or the like) configured to connect input devices (e.g., a keyboard, microphone, mouse, or other pointing device), output devices (e.g., video display, speaker, refreshable Braille terminal, or printer), or additional memory devices (e.g., portable flash drive or external media drive). In some implementations an I/O device is incorporated into the computing system 210, e.g., a touch screen on a tablet device. In some implementations, a computing device 210 includes an additional device 280 such as a co-processor, e.g., a math co-processor that is configured to assist the processor 250 with high precision or complex calculations.

Although the devices, systems, and methods described above are primarily described in the context of the operation of a fuel dispenser, one skilled in the art will appreciate that the devices, systems, and methods could be incorporated into a variety of components that include a card reader, such as ATMs, electrical charging kiosks (such as for an electric vehicle), air machines (such as for providing air to tires), vending machines, payment kiosks, and the like.

One skilled in the art will appreciate further features and advantages of the devices, systems, and methods based on the above-described embodiments. Accordingly, this disclosure is not to be limited by what has been particularly shown and described, except as indicated by the appended claims. All publications and references cited herein are expressly incorporated herein by reference in their entirety for all purposes.

Those skilled in the art will understand that the systems, devices and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present invention.

The present disclosure has been described above by way of example only within the context of the overall disclosure provided herein. It will be appreciated that modifications within the spirit and scope of the claims may be made without departing from the overall scope of the present disclosure.

What is claimed is:

1. A testing system, comprising:
a testing device having a first portion and a second portion;
wherein the first portion of the testing device includes an indicator configured to indicate a result of testing;
the second portion of the testing device includes an electrical contact;
the second portion of the testing device is configured to be inserted into a slot of a card reader configured to read a chip of a chip card; and
with the second portion of the testing device inserted as fully as possible into the slot, the indicator is configured to be activated if the electrical contact is operatively engaged with a chip reader of the card reader and to not be activated if the electrical contact is not operatively engaged with the chip reader of the card reader.

2. The system of claim 1, wherein the testing device includes an electrical path between the indicator and the electrical contact;
in a default state the electrical path is incomplete such that the indicator is not activated; and
with the second portion of the testing device inserted as fully as possible into the slot, the electrical path is configured to be complete between the indicator and the electrical contact.

3. The system of claim 2, wherein the indicator includes a light, the indicator being activated includes the light being illuminated, and the indicator not being activated includes the light not being illuminated.

4. The system of claim 1, wherein, with the second portion of the testing device inserted as fully as possible into the slot, the indicator not being activated is indicative of foreign matter being present in the slot.

5. The system of claim 1, wherein, with the second portion of the testing device inserted as fully as possible into the slot, the first portion of the testing device is located outside of the slot.

6. The system of claim 1, further comprising the card reader including the chip reader.

7. The system of claim 6, wherein the chip reader includes a chip pin configured to operatively engage the electrical contact.

8. The system of claim 7, wherein the testing device includes an electrical path between the indicator and the electrical contact;
in a default state the electrical path is incomplete such that the indicator is not activated; and
with the second portion of the testing device inserted as fully as possible into the slot, the chip pin is configured to operatively engage the electrical contact so as to complete the electrical path between the indicator and the electrical contact.

9. The system of claim 6, wherein a payment terminal includes the card reader, and the payment terminal is a fuel dispenser.

10. The system of claim 6, wherein a payment terminal includes the card reader, and the payment terminal is one of a fuel dispenser, an automatic teller machine, an electrical charging kiosk, an air machine, and a vending machine.

11. A testing method, comprising:
inserting the second portion of the testing device of claim 1 as fully as possible into the slot of claim 1 such that the indicator is either activated or not activated.

12. The method of claim 11, wherein a payment terminal includes the card reader, and the payment terminal is one of a fuel dispenser, an automatic teller machine, an electrical charging kiosk, an air machine, and a vending machine.

13. A testing system, comprising:
a testing device including an indicator, an electrical contact, and an electrical path between the light and the electrical contact, the indicator being configured to indicate a result of testing; and
a card reader of a payment terminal, the card reader including a slot and a chip reader;
wherein, in a default state, the electrical path is incomplete and the indicator is not activated;
the testing device is configured to be partially inserted into the slot such that the electrical contact is operatively engaged with the chip reader; and
the electrical contact operatively engaging with the chip reader is configured to complete the electrical path and thereby cause the indicator to be activated.

14. The system of claim 13, with the testing device inserted as fully as possible into the slot, the indicator not being activated is indicative of foreign matter being present in the slot.

15. The system of claim 14, wherein the indicator includes a light, the indicator being activated includes the light being illuminated, and the indicator not being activated includes the light not being illuminated.

16. The system of claim 13, wherein the chip reader includes a chip pin configured to operatively engage the electrical contact.

17. The system of claim 13, wherein the payment terminal is a fuel dispenser.

18. The system of claim 13, wherein the payment terminal is one of a fuel dispenser, an automatic teller machine, an electrical charging kiosk, an air machine, and a vending machine.

19. A testing method, comprising:
partially inserting the testing device of claim 13 into the slot of the card reader of claim 13 such that the indicator is either activated or not activated.

20. The method of claim 19, wherein the indicator not being activated is indicative of foreign matter being present in the slot, and the indicator being activated is indicative of foreign matter not being present in the slot.

21. The method of claim 19, wherein the payment terminal is one of a fuel dispenser, an automatic teller machine, an electrical charging kiosk, an air machine, and a vending machine.
